(19) United States
(12) Patent Application Publication
(10) Pub. No.: US 2026/0039313 A1
(43) Pub. Date: Feb. 5, 2026

(54) TECHNIQUES FOR RETRANSMITTING NONCOHERENT PEAKY WAVEFORMS IN WIRELESS COMMUNICATIONS

(71) Applicant: QUALCOMM Incorporated, San Diego, CA (US)

(72) Inventors: Yavuz Yapici, Florham Park, NJ (US); Juergen Cezanne, Ocean Township, NJ (US); Junyi Li, Greentown, PA (US)

(21) Appl. No.: 18/792,196

(22) Filed: Aug. 1, 2024

(51) Int. Cl. H03M 13/09; H04L 1/00; H04L 5/00

(52) U.S. Cl. CPC H03M 13/09; H04L 1/0041; H04L 1/0045; H04L 5/0055

(57) ABSTRACT

Aspects described herein relate to transmitting noncoherent peaky waveforms including multiplexing message data, to be transmitted to a receiving node, with redundancy bits on a per-message or per-symbol basis, transmitting, to the receiving node, the multiplexed message data and redundancy bits in a different subset of assigned subcarriers in each of multiple symbols of a noncoherent transmission according to a duty cycle, receiving, from the receiving node, a negative-acknowledgement (NACK) feedback for at least a portion of the message data or redundancy bits, and retransmitting, to the receiving node and based on receiving the NACK feedback, at least the portion of the message data or redundancy bits. Other aspects relate to receiving the multiplexed data transmissions, sending the NACK feedback, and receiving retransmissions of the multiplexed data.

### FIELD OF THE DISCLOSURE

Aspects of the present disclosure relate generally to wireless communication systems, and more particularly, to noncoherent peaky waveform transmission.

### DESCRIPTION OF RELATED ART

Wireless communication systems are widely deployed to provide various types of communication content such as voice, video, packet data, messaging, broadcast, and so on. These systems may be multiple-access systems capable of supporting communication with multiple users by sharing the available system resources (e.g., time, frequency, and power). Examples of such multiple-access systems include code-division multiple access (CDMA) systems, time-division multiple access (TDMA) systems, frequency-division multiple access (FDMA) systems, and orthogonal frequency-division multiple access (OFDMA) systems, and single-carrier frequency division multiple access (SC-FDMA) systems.

These multiple access technologies have been adopted in various telecommunication standards to provide a common protocol that enables different wireless devices to communicate on a municipal, national, regional, and even global level. For example, a fifth generation (5G) wireless communications technology (which can be referred to as 5G new radio (5G NR)) is envisaged to expand and support diverse usage scenarios and applications with respect to current mobile network generations. In an aspect, 5G communications technology can include: enhanced mobile broadband addressing human-centric use cases for access to multimedia content, services and data; ultra-reliable-low latency communications (URLLC) with certain specifications for latency and reliability; and massive machine type communications, which can allow a very large number of connected devices and transmission of a relatively low volume of non-delay-sensitive information.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

According to an aspect, an apparatus for wireless communication is provided that includes a transceiver, one or more memories configured to, individually or in combination, store instructions, and one or more processors communicatively coupled with the one or more memories. The one or more processors are, individually or in combination, configured to execute the instructions to cause the apparatus to multiplex message data, to be transmitted to a receiving node, with redundancy bits on a per-message or per-symbol basis, transmit, to the receiving node, the multiplexed message data and redundancy bits in a different subset of assigned subcarriers in each of multiple symbols of a noncoherent transmission according to a duty cycle, receive, from the receiving node, a negative-acknowledgement (NACK) feedback for at least a portion of the message data or redundancy bits, and retransmit, to the receiving node and based on receiving the NACK feedback, at least the portion of the message data or redundancy bits.

In another aspect, an apparatus for wireless communication is provided that includes a transceiver, one or more memories configured to, individually or in combination, store instructions, and one or more processors communicatively coupled with the one or more memories. The one or more processors are, individually or in combination, configured to execute the instructions to cause the apparatus to receive, from a transmitting node, message data and redundancy bits multiplexed in a different subset of assigned subcarriers in each of multiple symbols of a noncoherent transmission according to a duty cycle, perform a cyclic redundancy check (CRC) or forward error correction (FEC) for at least a portion of the message data or redundancy bits, transmit, to the transmitting node, a NACK feedback for at least the portion of the message data or redundancy bits, and receive, from the transmitting node and based on transmitting the NACK feedback, a retransmission of at least the portion of the message data or redundancy bits.

In another aspect, a method for wireless communication at a transmitting node is provided that includes multiplexing message data, to be transmitted to a receiving node, with redundancy bits on a per-message or per-symbol basis, transmitting, to the receiving node, the multiplexed message data and redundancy bits in a different subset of assigned subcarriers in each of multiple symbols of a noncoherent transmission according to a duty cycle, receiving, from the receiving node, a NACK feedback for at least a portion of the message data or redundancy bits, and retransmitting, to the receiving node and based on receiving the NACK feedback, at least the portion of the message data or redundancy bits.

In another aspect, a method for wireless communication at a receiving node is provided that includes receiving, from a transmitting node, message data and redundancy bits multiplexed in a different subset of assigned subcarriers in each of multiple symbols of a noncoherent transmission according to a duty cycle, performing a CRC or FEC for at least a portion of the message data or redundancy bits, transmitting, to the transmitting node, a NACK feedback for at least the portion of the message data or redundancy bits, and receiving, from the transmitting node and based on transmitting the NACK feedback, a retransmission of at least the portion of the message data or redundancy bits.

In a further aspect, an apparatus for wireless communication is provided that includes a transceiver, a memory configured to store instructions, and one or more processors communicatively coupled with the transceiver and the memory. The one or more processors are configured to execute the instructions to perform the operations of methods described herein. In another aspect, an apparatus for wireless communication is provided that includes means for performing the operations of methods described herein. In yet another aspect, a computer-readable medium is provided including code executable by one or more processors to perform the operations of methods described herein.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 illustrates an example of a wireless communication system, in accordance with various aspects of the present disclosure;

FIG. 2 is a diagram illustrating an example of disaggregated base station architecture, in accordance with various aspects of the present disclosure;

FIG. 3 is a block diagram illustrating an example of a user equipment (UE), in accordance with various aspects of the present disclosure;

FIG. 4 is a block diagram illustrating an example of a base station, in accordance with various aspects of the present disclosure;

FIG. 5 is a flow chart illustrating an example of a method for transmitting or retransmitting noncoherent peaky waveforms, in accordance with aspects described herein;

FIG. 6 is a flow chart illustrating an example of a method for receiving and/or processing a transmission or retransmission of a noncoherent peaky waveforms, in accordance with aspects described herein;

FIG. 7 illustrates an example of a communication timeline between a transmitting node and receiving node based on per-message multiplexing of message data and parity bits, in accordance with aspects described herein;

FIG. 8 illustrates an example of a communication timeline between a transmitting node and receiving node based on per-symbol multiplexing of message data and parity bits, in accordance with aspects described herein; and

FIG. 9 is a block diagram illustrating an example of a multiple-input multiple-output (MIMO) communication system including a base station and a UE, in accordance with various aspects of the present disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

The described features generally relate to retransmitting noncoherent peaky waveforms in wireless communications. In wireless communication technologies, such as fifth generation (5G) new radio (NR) or other wireless communication technologies, devices (e.g., user equipment (UE) and/or base stations/gNBs, etc.) can communicate using coherent or noncoherent transmissions. Coherent transmissions can be based on a tracking carrier phase with channel state information (CSI) estimation being performed at a receiving node and/or also a pilot sequence (e.g., based on a demodulation reference signal (DMRS)) for performing channel estimation to decode wireless communications, which is needed to improve reliability of the coherent transmissions. Noncoherent transmissions may not require tracking carrier phase and/or a pilot sequence, which can improve time/frequency resources utilization at the cost of reliability. In some examples, noncoherent transmissions may be beneficial over coherent transmissions. For example, acquiring reliable CSI at the receiving node can be problematic for low received power and/or signal-to-noise ratio (SNR), which may occur under high pathloss or wideband scenarios, where received energy per spectrum unit (e.g., hertz (Hz)) may be low under a fixed transmit power. When reliably obtaining CSI (e.g., to a precision sufficient for coherent detection) is infeasible, non-coherent transmission without any CSI acquisition at the receiving node (e.g., no pilot transmission) may be used.

A peaky transmission is one type of noncoherent transmission that is transmitted according to a duty cycle and such that the transmit power is concentrated over time and frequency (e.g., transmitted over a selection of tones that do not include all tones in allocated bandwidth). For example, in transmitting a peaky transmission, a transmitting node can apply the duty cycle to the transmission so that the transmission occurs in a fraction of time (e.g., only portion of time resources that are allocated for the transmission) and using increased peak transmit power (e.g., in proportion to the inverse of the duty cycle) over the selected portion of time/frequency resources. Thus, the transmitting node may transmit the peaky transmission over less than all allocated time resources and using less than all allocated frequency resource, but using increased transmit power over the time and/or frequency resources selected for transmission. In a peaky transmission, for example, each pulse can be transmitted with a duty cycle of θ such that θ<1, and a peak power of

$$\frac{{P}_{avg}}{θ}$$

where P_{avg} is the average power, and

$${P}_{peak} = \frac{{P}_{avg}}{θ} ≫ {P}_{avg} .$$

Peaky transmissions can improve reliability of the transmission at a receiving node by using the concentrated power over the selection of time and/or frequency resources.

When the message to be transmitted by peaky waveforms is of a certain length, however, multiple peaky symbols may need to be scheduled in time with a duty cycle, and the message may be received correctly only if all of these symbols are received without any error. This may deteriorate the overall error performance for communications (without any retransmission) as the number of peaky symbols representing a single message increases. One way to cope with degrading error performance can be to consider retransmission mechanisms, which are not available nor straightforward considering waveform characteristic of peaky waveforms and less-capable devices. Accordingly, aspects described herein relate to providing retransmission mechanisms for peaky transmission, which may consider scenarios with error detection and/or correction, along with unique device characteristics (e.g., in terms of processing power and energy budget) and unique waveform features. This can be used by devices (e.g., UEs) in low energy condition, and can provide reduced signaling overhead, improved energy efficiency, and the ability to connect massive intelligent devices (e.g., ambient Internet-of-Things (IOT) devices) to cellular ecosystem.

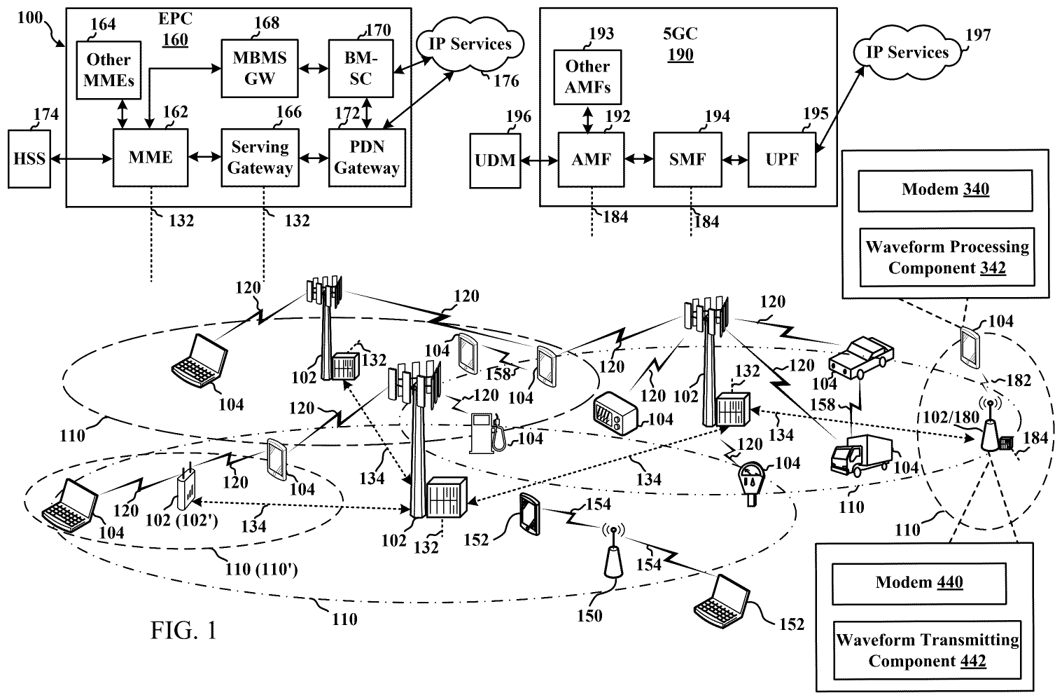

The described features will be presented in more detail below with reference to FIGS. 1-9.

As used in this application, the terms “component,” “module,” “system” and the like are intended to include a computer-related entity, such as but not limited to hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component can be localized on one computer and/or distributed between two or more computers. In addition, these components can execute from various computer readable media having various data structures stored thereon. The components can communicate by way of local and/or remote processes such as in accordance with a signal having one or more data packets, such as data from one component interacting with another component in a local system, distributed system, and/or across a network such as the Internet with other systems by way of the signal.

As used herein, a processor, at least one processor, and/or one or more processors, individually or in combination, configured to perform or operable for performing a plurality of actions is meant to include at least two different processors able to perform different, overlapping or non-overlapping subsets of the plurality actions, or a single processor able to perform all of the plurality of actions. In one non-limiting example of multiple processors being able to perform different ones of the plurality of actions in combination, a description of a processor, at least one processor, and/or one or more processors configured or operable to perform actions X, Y, and Z may include at least a first processor configured or operable to perform a first subset of X, Y, and Z (e.g., to perform X) and at least a second processor configured or operable to perform a second subset of X, Y, and Z (e.g., to perform Y and Z). Alternatively, a first processor, a second processor, and a third processor may be respectively configured or operable to perform a respective one of actions X, Y, and Z. It should be understood that any combination of one or more processors each may be configured or operable to perform any one or any combination of a plurality of actions.

As used herein, a memory, at least one memory, and/or one or more memories, individually or in combination, configured to store or having stored thereon instructions executable by one or more processors for performing a plurality of actions is meant to include at least two different memories able to store different, overlapping or non-overlapping subsets of the instructions for performing different, overlapping or non-overlapping subsets of the plurality actions, or a single memory able to store the instructions for performing all of the plurality of actions. In one non-limiting example of one or more memories, individually or in combination, being able to store different subsets of the instructions for performing different ones of the plurality of actions, a description of a memory, at least one memory, and/or one or more memories configured or operable to store or having stored thereon instructions for performing actions X, Y, and Z may include at least a first memory configured or operable to store or having stored thereon a first subset of instructions for performing a first subset of X, Y, and Z (e.g., instructions to perform X) and at least a second memory configured or operable to store or having stored thereon a second subset of instructions for performing a second subset of X, Y, and Z (e.g., instructions to perform Y and Z). Alternatively, a first memory, and second memory, and a third memory may be respectively configured to store or have stored thereon a respective one of a first subset of instructions for performing X, a second subset of instruction for performing Y, and a third subset of instructions for performing Z. It should be understood that any combination of one or more memories each may be configured or operable to store or have stored thereon any one or any combination of instructions executable by one or more processors to perform any one or any combination of a plurality of actions. Moreover, one or more processors may each be coupled to at least one of the one or more memories and configured or operable to execute the instructions to perform the plurality of actions. For instance, in the above non-limiting example of the different subset of instructions for performing actions X, Y, and Z, a first processor may be coupled to a first memory storing instructions for performing action X, and at least a second processor may be coupled to at least a second memory storing instructions for performing actions Y and Z, and the first processor and the second processor may, in combination, execute the respective subset of instructions to accomplish performing actions X, Y, and Z. Alternatively, three processors may access one of three different memories each storing one of instructions for performing X, Y, or Z, and the three processor may in combination execute the respective subset of instruction to accomplish performing actions X, Y, and Z. Alternatively, a single processor may execute the instructions stored on a single memory, or distributed across multiple memories, to accomplish performing actions X, Y, and Z.

Techniques described herein may be used for various wireless communication systems such as CDMA, TDMA, FDMA, OFDMA, single carrier-FDMA, and other systems. The terms “system” and “network” may often be used interchangeably. A CDMA system may implement a radio technology such as CDMA2000, Universal Terrestrial Radio Access (UTRA), etc. CDMA2000 covers IS-2000, IS-95, and IS-856 standards. IS-2000 Releases 0 and A are commonly referred to as CDMA2000 1×, 1×, etc. IS-856 (TIA-856) is commonly referred to as CDMA2000 1×EV-DO, High Rate Packet Data (HRPD), etc. UTRA includes Wideband CDMA (WCDMA) and other variants of CDMA. A TDMA system may implement a radio technology such as Global System for Mobile Communications (GSM). An OFDMA system may implement a radio technology such as Ultra Mobile Broadband (UMB), Evolved UTRA (E-UTRA), IEEE 802.11 (Wi-Fi), IEEE 802.16 (WiMAX), IEEE 802.20, Flash-OFDM™, etc. UTRA and E-UTRA are part of Universal Mobile Telecommunication System (UMTS). 3GPP Long Term Evolution (LTE) and LTE-Advanced (LTE-A) are new releases of UMTS that use E-UTRA. UTRA, E-UTRA, UMTS, LTE, LTE-A, and GSM are described in documents from an organization named “3rd Generation Partnership Project” (3GPP). CDMA2000 and UMB are described in documents from an organization named “3rd Generation Partnership Project 2” (3GPP2). The techniques described herein may be used for the systems and radio technologies mentioned above as well as other systems and radio technologies, including cellular (e.g., LTE) communications over a shared radio frequency spectrum band. The description below, however, describes an LTE/LTE-A system for purposes of example, and LTE terminology is used in much of the description below, although the techniques are applicable beyond LTE/LTE-A applications (e.g., to fifth generation (5G) new radio (NR) networks or other next generation communication systems).

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in other examples.

Various aspects or features will be presented in terms of systems that can include a number of devices, components, modules, and the like. It is to be understood and appreciated that the various systems can include additional devices, components, modules, etc. and/or may not include all of the devices, components, modules etc. discussed in connection with the figures. A combination of these approaches can also be used.

FIG. 1 is a diagram illustrating an example of a wireless communications system and an access network 100. The wireless communications system (also referred to as a wireless wide area network (WWAN)) can include base stations 102, UEs 104, an Evolved Packet Core (EPC) 160, and/or a 5G Core (5GC) 190. The base stations 102 may include macro cells (high power cellular base station) and/or small cells (low power cellular base station). The macro cells can include base stations. The small cells can include femtocells, picocells, and microcells. In an example, the base stations 102 may also include gNBs 180, as described further herein. In one example, some nodes of the wireless communication system may have a modem 340 and waveform processing component 342 for processing transmissions and/or retransmissions of noncoherent peaky waveforms, in accordance with aspects described herein. In addition, some nodes may have a modem 440 and waveform transmitting component 442 for transmitting and/or retransmitting noncoherent peaky waveforms, in accordance with aspects described herein. Though a UE 104 is shown as having the modem 340 and waveform processing component 342 and a base station 102/gNB 180 is shown as having the modem 440 and waveform transmitting component 442, this is one illustrative example, and substantially any node or type of node may include a modem 340 and waveform processing component 342 and/or a modem 440 and waveform transmitting component 442 for providing corresponding functionalities described herein.

The base stations 102 configured for 4G LTE (which can collectively be referred to as Evolved Universal Mobile Telecommunications System (UMTS) Terrestrial Radio Access Network (E-UTRAN)) may interface with the EPC 160 through backhaul links 132 (e.g., using an SI interface). The base stations 102 configured for 5G NR (which can collectively be referred to as Next Generation RAN (NG-RAN)) may interface with 5GC 190 through backhaul links 184. In addition to other functions, the base stations 102 may perform one or more of the following functions: transfer of user data, radio channel ciphering and deciphering, integrity protection, head compression, mobility control functions (e.g., handover, dual connectivity), inter-cell interference coordination, connection setup and release, load balancing, distribution for non-access stratum (NAS) messages, NAS node selection, synchronization, radio access network (RAN) sharing, multimedia broadcast multicast service (MBMS), subscriber and equipment trace, RAN information management (RIM), paging, positioning, and delivery of warning messages. The base stations 102 may communicate directly or indirectly (e.g., through the EPC 160 or 5GC 190) with each other over backhaul links 134 (e.g., using an X2 interface). The backhaul links 134 may be wired or wireless.

The base stations 102 may wirelessly communicate with one or more UEs 104. Each of the base stations 102 may provide communication coverage for a respective geographic coverage area 110. There may be overlapping geographic coverage areas 110. For example, the small cell 102′ may have a coverage area 110′ that overlaps the coverage area 110 of one or more macro base stations 102. A network that includes both small cell and macro cells may be referred to as a heterogeneous network. A heterogeneous network may also include Home Evolved Node Bs (eNBs) (HeNBs), which may provide service to a restricted group, which can be referred to as a closed subscriber group (CSG). The communication links 120 between the base stations 102 and the UEs 104 may include uplink (UL) (also referred to as reverse link) transmissions from a UE 104 to a base station 102 and/or downlink (DL) (also referred to as forward link) transmissions from a base station 102 to a UE 104. The communication links 120 may use multiple-input and multiple-output (MIMO) antenna technology, including spatial multiplexing, beamforming, and/or transmit diversity. The communication links may be through one or more carriers. The base stations 102/UEs 104 may use spectrum up to Y MHz (e.g., 5, 10, 15, 20, 100, 400, etc. MHz) bandwidth per carrier allocated in a carrier aggregation of up to a total of Yx MHz (e.g., for x component carriers) used for transmission in the DL and/or the UL direction. The carriers may or may not be adjacent to each other. Allocation of carriers may be asymmetric with respect to DL and UL (e.g., more or less carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

In another example, certain UEs 104 may communicate with each other using device-to-device (D2D) communication link 158. The D2D communication link 158 may use the DL/UL WWAN spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, FlashLinQ, WiMedia, Bluetooth, ZigBee, Wi-Fi based on the IEEE 802.11 standard, LTE, or NR.

The wireless communications system may further include a Wi-Fi access point (AP) 150 in communication with Wi-Fi stations (STAs) 152 via communication links 154 in a 5 GHz unlicensed frequency spectrum. When communicating in an unlicensed frequency spectrum, the STAs 152/AP 150 may perform a clear channel assessment (CCA) prior to communicating in order to determine whether the channel is available.

The small cell 102′ may operate in a licensed and/or an unlicensed frequency spectrum. When operating in an unlicensed frequency spectrum, the small cell 102′ may employ NR and use the same 5 GHz unlicensed frequency spectrum as used by the Wi-Fi AP 150. The small cell 102′, employing NR in an unlicensed frequency spectrum, may boost coverage to and/or increase capacity of the access network.

A base station 102, whether a small cell 102′ or a large cell (e.g., macro base station), may include an eNB, gNodeB (gNB), or other type of base station. Some base stations, such as gNB 180 may operate in a traditional sub 6 GHz spectrum, in millimeter wave (mmW) frequencies, and/or near mmW frequencies in communication with the UE 104. When the gNB 180 operates in mmW or near mmW frequencies, the gNB 180 may be referred to as an mmW base station. Extremely high frequency (EHF) is part of the RF in the electromagnetic spectrum. EHF has a range of 30 GHz to 300 GHz and a wavelength between 1 millimeter and 10 millimeters. Radio waves in the band may be referred to as a millimeter wave. Near mmW may extend down to a frequency of 3 GHZ with a wavelength of 100 millimeters. The super high frequency (SHF) band extends between 3 GHz and 30 GHz, also referred to as centimeter wave. Communications using the mmW/near mmW radio frequency band has extremely high path loss and a short range. The mmW base station 180 may utilize beamforming 182 with the UE 104 to compensate for the extremely high path loss and short range. A base station 102 referred to herein can include a gNB 180.

The EPC 160 may include a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and a Packet Data Network (PDN) Gateway 172. The MME 162 may be in communication with a Home Subscriber Server (HSS) 174. The MME 162 is the control node that processes the signaling between the UEs 104 and the EPC 160. Generally, the MME 162 provides bearer and connection management. All user Internet protocol (IP) packets are transferred through the Serving Gateway 166, which itself is connected to the PDN Gateway 172. The PDN Gateway 172 provides UE IP address allocation as well as other functions. The PDN Gateway 172 and the BM-SC 170 are connected to the IP Services 176. The IP Services 176 may include the Internet, an intranet, an IP Multimedia Subsystem (IMS), a PS Streaming Service, and/or other IP services. The BM-SC 170 may provide functions for MBMS user service provisioning and delivery. The BM-SC 170 may serve as an entry point for content provider MBMS transmission, may be used to authorize and initiate MBMS Bearer Services within a public land mobile network (PLMN), and may be used to schedule MBMS transmissions. The MBMS Gateway 168 may be used to distribute MBMS traffic to the base stations 102 belonging to a Multicast Broadcast Single Frequency Network (MBSFN) area broadcasting a particular service, and may be responsible for session management (start/stop) and for collecting eMBMS related charging information.

The 5GC 190 may include a Access and Mobility Management Function (AMF) 192, other AMFs 193, a Session Management Function (SMF) 194, and a User Plane Function (UPF) 195. The AMF 192 may be in communication with a Unified Data Management (UDM) 196. The AMF 192 can be a control node that processes the signaling between the UEs 104 and the 5GC 190. Generally, the AMF 192 can provide QoS flow and session management. User Internet protocol (IP) packets (e.g., from one or more UEs 104) can be transferred through the UPF 195. The UPF 195 can provide UE IP address allocation for one or more UEs, as well as other functions. The UPF 195 is connected to the IP Services 197. The IP Services 197 may include the Internet, an intranet, an IP Multimedia Subsystem (IMS), a PS Streaming Service, and/or other IP services.

The base station may also be referred to as a gNB, Node B, evolved Node B (eNB), an access point, a base transceiver station, a radio base station, a radio transceiver, a transceiver function, a basic service set (BSS), an extended service set (ESS), a transmit reception point (TRP), or some other suitable terminology. The base station 102 provides an access point to the EPC 160 or 5GC 190 for a UE 104. Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). IoT UEs may include machine type communication (MTC)/enhanced MTC (cMTC, also referred to as category (CAT)-M, Cat M1) UEs, NB-IOT (also referred to as CAT NB1) UEs, as well as other types of UEs. In the present disclosure, eMTC and NB-IOT may refer to future technologies that may evolve from or may be based on these technologies. For example, eMTC may include FeMTC (further eMTC), cFcMTC (enhanced further eMTC), mMTC (massive MTC), etc., and NB-IOT may include eNB-IoT (enhanced NB-IOT), FeNB-IOT (further enhanced NB-IOT), etc. The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology.

Deployment of communication systems, such as 5G new radio (NR) systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS, e.g., BS 102), or one or more units (or one or more components) performing base station functionality, may be implemented in an aggregated or disaggregated architecture. For example, a BS (such as a Node B (NB), evolved NB (eNB), NR BS, 5G NB, access point (AP), a transmit receive point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU also can be implemented as virtual units, i.e., a virtual central unit (VCU), a virtual distributed unit (VDU), or a virtual radio unit (VRU).

Base station-type operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

In an example, waveform transmitting component 442 of a base station 102/gNB 180 can transmit noncoherent peaky waveforms to a UE 104, which may include multiplexing message data and redundancy bits on a per-message or per-symbol basis, and transmitting the multiplexed data in peaky transmissions over a period of time (e.g., in each of multiple symbols of a noncoherent transmission according to a duty cycle). Where the multiplexing is per-message, waveform processing component 342 of a UE 104 can receive and process each of the transmissions (e.g., each symbol) of the message before attempting to decode the message and generating feedback for transmitting to the base station 102/gNB 180. In this example, waveform transmitting component 442 may retransmit the message if negative-acknowledgement (NACK) feedback is received. Where multiplexing is per-symbol, waveform processing component 342 of a UE 104 can receive and attempt to decode each symbol and generate feedback for transmitting to the base station 102/gNB 180 on a per-symbol basis. In this example, waveform transmitting component 442 may retransmit a symbol if negative-acknowledgement (NACK) feedback is received. As described, in some examples, the UE 104 can include the waveform transmitting component 442 for transmitting and/or retransmitting noncoherent peaky waveforms, and the base station 102/gNB 180 (or another UE 104 in sidelink communications) can include waveform processing component 342 for processing transmissions and/or retransmissions of noncoherent peaky waveforms.

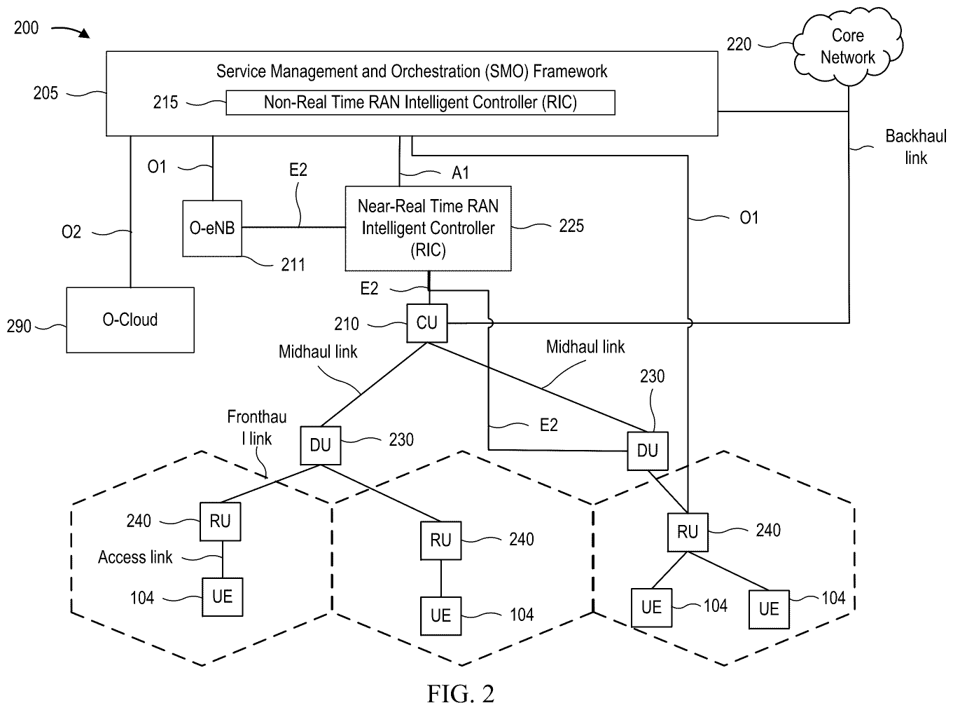

FIG. 2 shows a diagram illustrating an example of disaggregated base station 200 architecture. The disaggregated base station 200 architecture may include one or more central units (CUs) 210 that can communicate directly with a core network 220 via a backhaul link, or indirectly with the core network 220 through one or more disaggregated base station units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUs) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUS 210, the DUs 230, the RUs 240, as well as the Near-RT RICs 225, the Non-RT RICs 215 and the SMO Framework 205, may include one or more interfaces or be coupled to one or more interfaces configured to receive or transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or transmit signals over a wired transmission medium to one or more of the other units. Additionally, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (i.e., Central Unit-User Plane (CU-UP)), control plane functionality (i.e., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the E1 interface when implemented in an O-RAN configuration. The CU 210 can be implemented to communicate with the DU 230, as necessary, for network control and signaling.

The DU 230 may correspond to a logical unit that includes one or more base station functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the third Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (IFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communication with one or more UEs 104. In some implementations, real-time and non-real-time aspects of control and user plane communication with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUS 240 and Near-RT RICs 225. In some implementations, the SMO Framework 205 can communicate with a hardware aspect of a 4G RAN, such as an open eNB (O-cNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via O1) or via creation of RAN management policies (such as A1 policies).

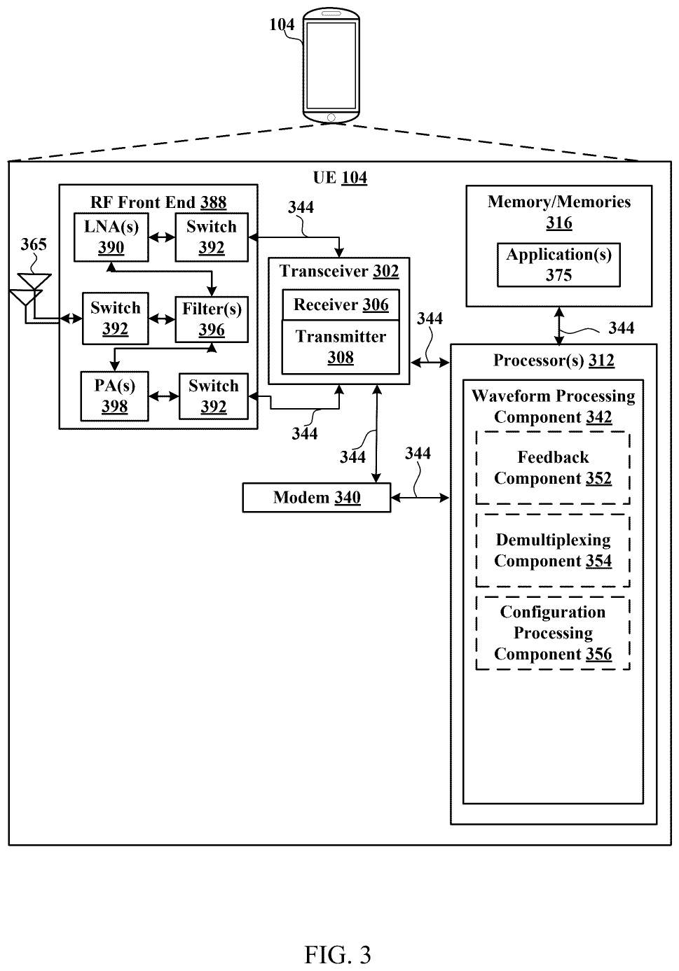

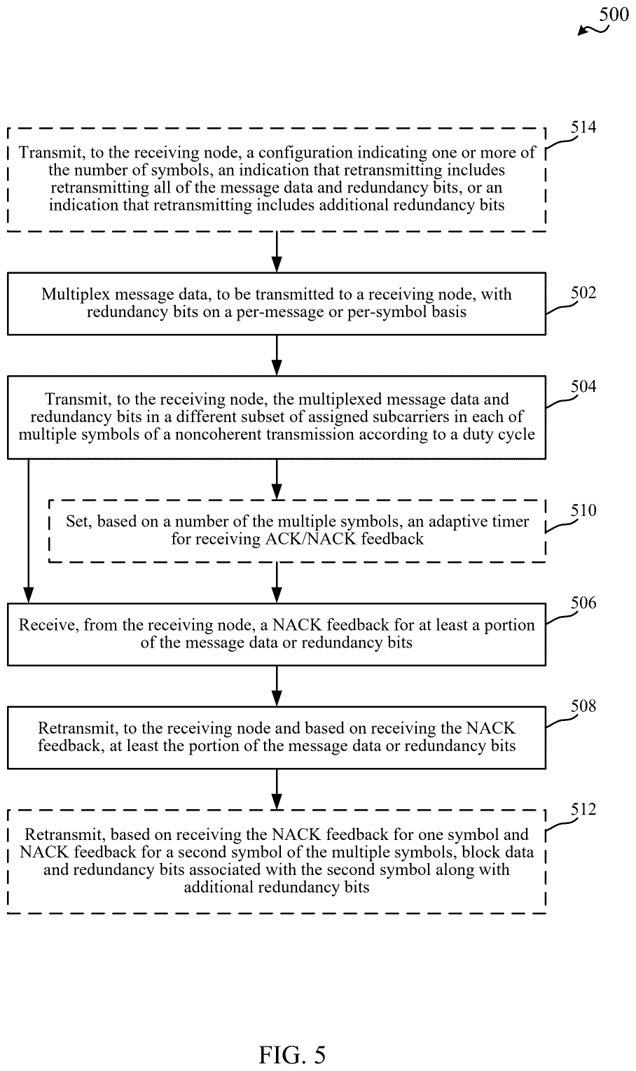

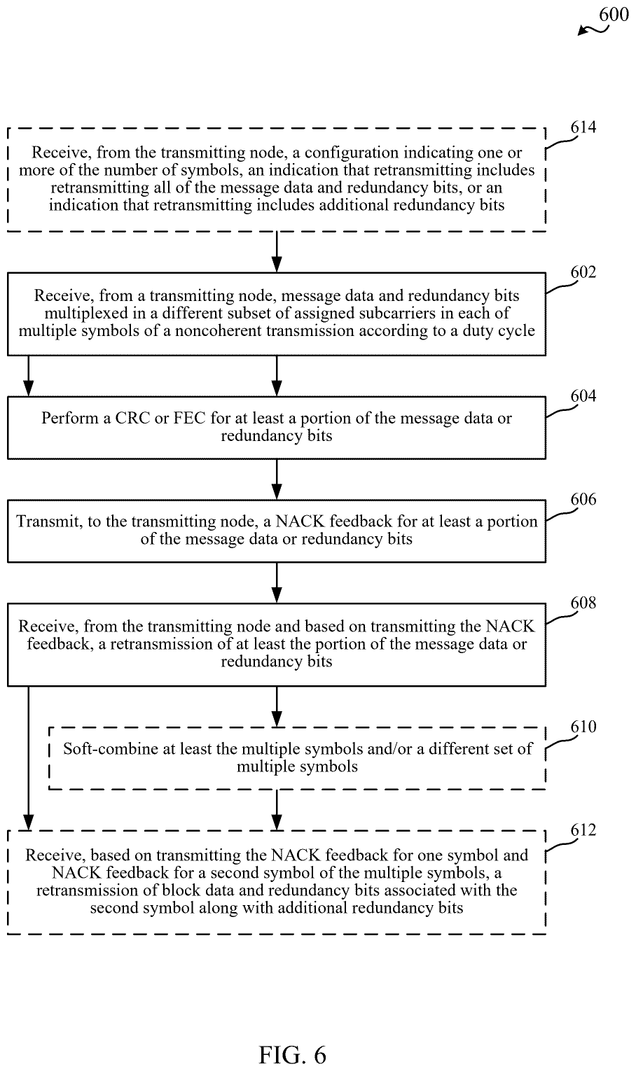

Turning now to FIGS. 3-9, aspects are depicted with reference to one or more components and one or more methods that may perform the actions or operations described herein, where aspects in dashed line may be optional. Although the operations described below in FIGS. 5 and 6 are presented in a particular order and/or as being performed by an example component, it should be understood that the ordering of the actions and the components performing the actions may be varied, depending on the implementation. Moreover, it should be understood that the following actions, functions, and/or described components may be performed by a specially programmed processor, a processor executing specially programmed software or computer-readable media, or by any other combination of a hardware component and/or a software component capable of performing the described actions or functions.

Referring to FIG. 3, one example of an implementation of UE 104 may include a variety of components, some of which have already been described above and are described further herein, including components such as one or more processors 312 and one or more memories 316 and one or more transceivers 302 in communication via one or more buses 344. For example, the one or more processors 312 can include a single processor or multiple processors configured to perform one or more functions described herein. For example, the multiple processors can be configured to perform a certain subset of a set of functions described herein, such that the multiple processors together can perform the set of functions. Similarly, for example, the one or more memories 316 can include a single memory device or multiple memory devices configured to store instructions or parameters for performing one or more functions described herein. For example, the multiple memory devices can be configured to store the instructions or parameters for performing a certain subset of a set of functions described herein, such that the multiple memory devices together can store the instructions or parameters for the set of functions. The one or more processors 312, one or more memories 316, and one or more transceivers 302 may operate in conjunction with modem 340 and/or waveform processing component 342 for processing transmissions and/or retransmissions of a noncoherent peaky waveform, in accordance with aspects described herein.

In an aspect, the one or more processors 312 can include a modem 340 and/or can be part of the modem 340 that uses one or more modem processors. Thus, the various functions related to waveform processing component 342 may be included in modem 340 and/or processors 312 and, in an aspect, can be executed by a single processor, while in other aspects, different ones of the functions may be executed by a combination of two or more different processors. For example, in an aspect, the one or more processors 312 may include any one or any combination of a modem processor, or a baseband processor, or a digital signal processor, or a transmit processor, or a receiver processor, or a transceiver processor associated with transceiver 302. In other aspects, some of the features of the one or more processors 312 and/or modem 340 associated with waveform processing component 342 may be performed by transceiver 302.

Also, memory/memories 316 may be configured to store data used herein and/or local versions of applications 375 or waveform processing component 342 and/or one or more of its subcomponents being executed by at least one processor 312. Memory/memories 316 can include any type of computer-readable medium usable by a computer or at least one processor 312, such as random access memory (RAM), read only memory (ROM), tapes, magnetic discs, optical discs, volatile memory, non-volatile memory, and any combination thereof. In an aspect, for example, memory/memories 316 may be a non-transitory computer-readable storage medium that stores one or more computer-executable codes defining waveform processing component 342 and/or one or more of its subcomponents, and/or data associated therewith, when UE 104 is operating at least one processor 312 to execute waveform processing component 342 and/or one or more of its subcomponents.

Transceiver 302 may include at least one receiver 306 and at least one transmitter 308. Receiver 306 may include hardware, firmware, and/or software code executable by a processor for receiving data, the code comprising instructions and being stored in a memory (e.g., computer-readable medium). Receiver 306 may be, for example, a radio frequency (RF) receiver. In an aspect, receiver 306 may receive signals transmitted by at least one base station 102. Additionally, receiver 306 may process such received signals, and also may obtain measurements of the signals, such as, but not limited to, Ec/Io, signal-to-noise ratio (SNR), reference signal received power (RSRP), received signal strength indicator (RSSI), etc. Transmitter 308 may include hardware, firmware, and/or software code executable by a processor for transmitting data, the code comprising instructions and being stored in a memory (e.g., computer-readable medium). A suitable example of transmitter 308 may including, but is not limited to, an RF transmitter.

Moreover, in an aspect, UE 104 may include RF front end 388, which may operate in communication with one or more antennas 365 and transceiver 302 for receiving and transmitting radio transmissions, for example, wireless communications transmitted by at least one base station 102 or wireless transmissions transmitted by UE 104. RF front end 388 may be connected to one or more antennas 365 and can include one or more low-noise amplifiers (LNAs) 390, one or more switches 392, one or more power amplifiers (PAS) 398, and one or more filters 396 for transmitting and receiving RF signals.

In an aspect, LNA 390 can amplify a received signal at a desired output level. In an aspect, each LNA 390 may have a specified minimum and maximum gain values. In an aspect, RF front end 388 may use one or more switches 392 to select a particular LNA 390 and its specified gain value based on a desired gain value for a particular application.

Further, for example, one or more PA(s) 398 may be used by RF front end 388 to amplify a signal for an RF output at a desired output power level. In an aspect, each PA 398 may have specified minimum and maximum gain values. In an aspect, RF front end 388 may use one or more switches 392 to select a particular PA 398 and its specified gain value based on a desired gain value for a particular application.

Also, for example, one or more filters 396 can be used by RF front end 388 to filter a received signal to obtain an input RF signal. Similarly, in an aspect, for example, a respective filter 396 can be used to filter an output from a respective PA 398 to produce an output signal for transmission. In an aspect, each filter 396 can be connected to a specific LNA 390 and/or PA 398. In an aspect, RF front end 388 can use one or more switches 392 to select a transmit or receive path using a specified filter 396, LNA 390, and/or PA 398, based on a configuration as specified by transceiver 302 and/or processor 312.

As such, transceiver 302 may be configured to transmit and receive wireless signals through one or more antennas 365 via RF front end 388. In an aspect, transceiver may be tuned to operate at specified frequencies such that UE 104 can communicate with, for example, one or more base stations 102 or one or more cells associated with one or more base stations 102. In an aspect, for example, modem 340 can configure transceiver 302 to operate at a specified frequency and power level based on the UE configuration of the UE 104 and the communication protocol used by modem 340.

In an aspect, modem 340 can be a multiband-multimode modem, which can process digital data and communicate with transceiver 302 such that the digital data is sent and received using transceiver 302. In an aspect, modem 340 can be multiband and be configured to support multiple frequency bands for a specific communications protocol. In an aspect, modem 340 can be multimode and be configured to support multiple operating networks and communications protocols. In an aspect, modem 340 can control one or more components of UE 104 (e.g., RF front end 388, transceiver 302) to enable transmission and/or reception of signals from the network based on a specified modem configuration. In an aspect, the modem configuration can be based on the mode of the modem and the frequency band in use. In another aspect, the modem configuration can be based on UE configuration information associated with UE 104 as provided by the network during cell selection and/or cell reselection.

In an aspect, waveform processing component 342 can optionally include a feedback component 352 for generating and/or transmitting feedback for transmission or retransmissions of noncoherent peaky waveforms, a demultiplexing component 354 for demultiplexing message data and parity bits from a message received in a noncoherent peaky waveform, and/or a configuration processing component 356 for processing one or more configurations provided to the UE 104 for processing noncoherent peaky waveform transmissions or retransmissions, in accordance with aspects described herein.

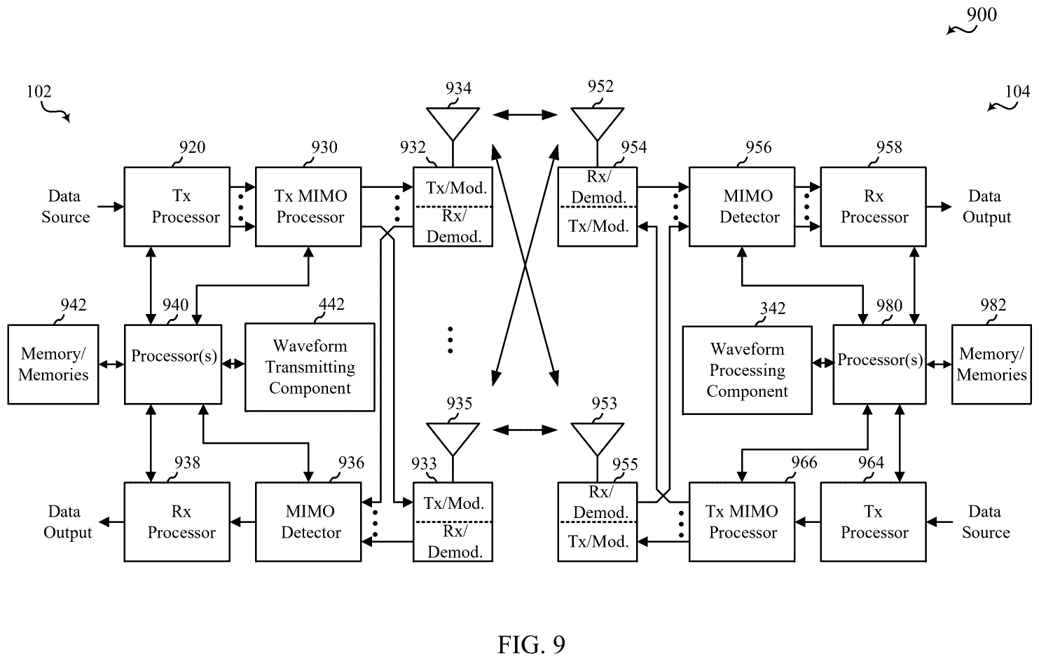

In an aspect, the processor(s) 312 may correspond to one or more of the processors described in connection with the UE in FIG. 9. Similarly, the memory/memories 316 may correspond to the one or more memories described in connection with the UE in FIG. 9.

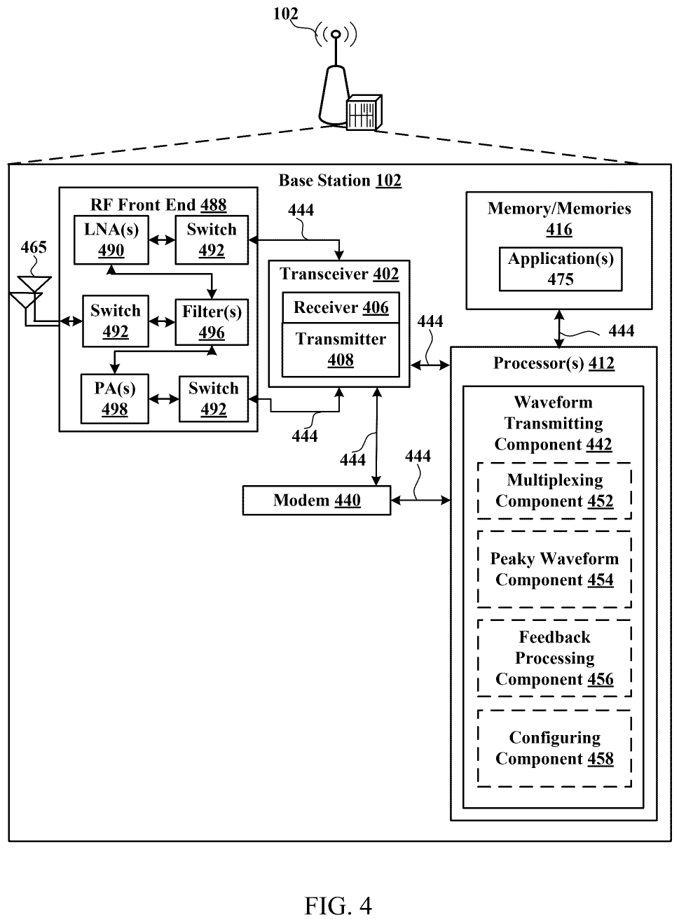

Referring to FIG. 4, one example of an implementation of base station 102 (e.g., a base station 102 and/or gNB 180, as described above) may include a variety of components, some of which have already been described above, but including components such as one or more processors 412 and one or more memories 416 and one or more transceivers 402 in communication via one or more buses 444. For example, the one or more processors 412 can include a single processor or multiple processors configured to perform one or more functions described herein. For example, the multiple processors can be configured to perform a certain subset of a set of functions described herein, such that the multiple processors together can perform the set of functions. Similarly, for example, the one or more memories 416 can include a single memory device or multiple memory devices configured to store instructions or parameters for performing one or more functions described herein. For example, the multiple memory devices can be configured to store the instructions or parameters for performing a certain subset of a set of functions described herein, such that the multiple memory devices together can store the instructions or parameters for the set of functions. The one or more processors 412, one or more memories 416, and one or more transceivers 402 may operate in conjunction with modem 440 and/or waveform transmitting component 442 for transmitting or retransmitting noncoherent peaky waveforms, in accordance with aspects described herein.

The transceiver 402, receiver 406, transmitter 408, one or more processors 412, memory/memories 416, applications 475, buses 444, RF front end 488, LNAs 490, switches 492, filters 496, PAs 498, and one or more antennas 465 may be the same as or similar to the corresponding components of UE 104, as described above, but configured or otherwise programmed for base station operations as opposed to UE operations.

In an aspect, waveform transmitting component 442 can optionally include a multiplexing component 452 for multiplexing message data and parity bits for transmitting in a noncoherent peaky transmission, a peaky waveform component 454 for generating a noncoherent peaky waveform for transmitting the multiplexed data, a feedback processing component 456 for receiving and/or processing feedback for a noncoherent peaky waveform transmission, and/or a configuring component 458 for generating and/or transmitting a configuration for a UE 104 indicating one or more parameters for processing noncoherent peaky transmissions, in accordance with aspects described herein.

In an aspect, the processor(s) 412 may correspond to one or more of the processors described in connection with the base station in FIG. 9. Similarly, the memory/memories 416 may correspond to the one or more memories described in connection with the base station in FIG. 9.

FIG. 5 illustrates a flow chart of an example of a method 500 for transmitting or retransmitting noncoherent peaky waveforms, in accordance with aspects described herein. FIG. 6 illustrates a flow chart of an example of a method 600 for receiving and/or processing a transmission or retransmission of a noncoherent peaky waveforms, in accordance with aspects described herein. In an example, a transmitting node, which may include a base station 102 or gNB 180, a monolithic base station or gNB, a portion of a disaggregated base station or gNB, a UE in sidelink communication, etc., can perform the functions described in method 500 shown in FIG. 5 using one or more of the components described in FIGS. 1 and/or 4. In an example, a receiving node, which may include a UE 104, a base station 102 or gNB 180, a monolithic base station or gNB, a portion of a disaggregated base station or gNB, etc., can perform the functions described in method 600 shown in FIG. 6 using one or more of the components described in FIGS. 1 and/or 3. Thus, though shown and described as a base station 102 transmitting and a UE 104 receiving the peaky waveform transmissions, it is to be appreciated that a UE 104 (or any transmitting node) can transmit, and a base station 102 (or another UE 104 or any receiving node) can receive, the peaky waveform transmissions. In addition, methods 500 and 600 are described in conjunction with one another for case of explanation; however, the methods 500 and 600 are not required to be performed together and indeed can be performed independently using separate devices.

In method 500, at Block 502, message data, to be transmitted to a receiving node, can be multiplexed with redundancy bits on a per-message or per-symbol basis. In an aspect, multiplexing component 452, e.g., in conjunction with processor(s) 412, memory/memories 416, transceiver 402, waveform transmitting component 442, etc., can multiplex the message data, to be transmitted to the receiving node (e.g., a UE 104 or base station 102/gNB 180), with redundancy bits on a per-message or per-symbol basis. For example, for a given message data to be transmitted to the receiving node (e.g., to be transmitted over a control channel, such as physical downlink control channel (PDCCH) or physical uplink control channel (PUCCH) or physical sidelink control channel (PSCCH), or over a data channel, such as physical downlink shared channel (PDSCH) or physical uplink shared channel (PUSCH) or physical sidelink shared channel (PSSCH), etc., multiplexing component 452 can multiplex the message with redundancy bits. For example, multiplexing component 452 can provide the message data and redundancy bits (e.g., cyclic redundancy check (CRC) or forward error correction (FEC) bits) as input to an interleaver to interleave the message data and redundancy bits to produce the message for transmission. In another example, multiplexing component 452 can partition the message data into multiple blocks, where each block is to be transmitted in a symbol, and can provide each block along with redundancy bits as input to an interleaver to interleave the block and redundancy bits to produce each symbol for transmission.

In method 500, at Block 504, the multiplexed message data and redundancy bits can be transmitted, to the receiving node, in a different subset of assigned subcarriers in each of multiple symbols of a noncoherent transmission according to a duty cycle. In an aspect, peaky waveform component 454, e.g., in conjunction with processor(s) 412, memory/memories 416, transceiver 402, waveform transmitting component 442, etc., can generate and/or transmit, to the receiving node, the multiplexed message data and redundancy bits in a different subset of assigned subcarriers in each of multiple symbols of a noncoherent transmission according to a duty cycle. As described, for example, a noncoherent peaky transmission can be defined by transmitting (e.g., increased or concentrated) signal energy in a portion of assigned subcarriers (or other frequency division) over portion of assigned symbols (or other time division) rather than using all subcarriers or all symbols allocated to the transmitting node for the transmission. For example, the subcarriers utilized for a given message can vary across symbols. In another example, the duty cycle can include symbols that are spaced substantially uniformly or nonuniformly in time. In an example, the receiving node can be configured with information regarding the utilized subcarriers and/or duty cycle or can blindly decode the peaky transmission in the subcarriers and/or symbols allocated for the transmission.

In method 600, at Block 602, the message data and redundancy bits can be received, from a transmitting node, as multiplexed in a different subset of assigned subcarriers in each of multiple symbols of a noncoherent transmission according to a duty cycle. In an aspect, waveform processing component 342, e.g., in conjunction with processor(s) 312, memory/memories 316, transceiver 302, etc., can receive and/or process, from the transmitting node (e.g., a base station 102/gNB 180 and/or UE 104), message data and redundancy bits multiplexed in a different subset of assigned subcarriers in each of multiple symbols of the noncoherent transmission according to the duty cycle. For example, waveform processing component 342 can receive one or more signals from the transmitting node in symbols or corresponding time periods based on the duty cycle, where the signals can have energy in the different subcarriers at each symbol, as described in relation to peaky transmissions herein.

In method 600, at Block 604, a CRC or FEC can be performed for at least a portion of the message data or redundancy bits. In an aspect, demultiplexing component 354, e.g., in conjunction with processor(s) 312, memory/memories 316, transceiver 302, waveform processing component 342, etc., can perform the CRC or FEC (or other decoding or demultiplexing procedure) for at least the portion of the message data or redundancy bits. In one example, where the multiplexing is per-message, demultiplexing component 354 can perform CRC or FEC over the message based on receiving multiple symbols that comprise the message. In another example, where the multiplexing is per-symbol, demultiplexing component 354 can perform the CRC or FEC on each symbol as received, in attempting to decode a block of the message, without necessarily waiting until all symbols that comprise the message are received.

In method 600, at Block 606, a NACK feedback can be transmitted, to the transmitting node, for at least a portion of the message data or redundancy bits. In an aspect, feedback component 352, e.g., in conjunction with processor(s) 312, memory/memories 316, transceiver 302, waveform processing component 342, etc., can transmit, to the transmitting node, the NACK feedback for at least the portion of the message data or redundancy bits. For example, feedback component 352 can generate the NACK feedback (or ACK or other feedback) based on an outcome of the CRC or FEC procedure (e.g., NACK feedback when CRC or FEC fails). Additionally, in this regard, feedback component 352 can generate the feedback for the message when multiplexing is per-message or can generate feedback for a block of the message when multiplexing is per-symbol. In an example, feedback component 352 can transmit the feedback at a configured time offset from the transmission of the multiplexed message data (e.g., a time offset from receiving the transmission of the multiplexed message data), which may be defined as a parameter K1_0 in 5G NR. In an example, the parameter may be configured for the receiving node and may correspond to a number of symbols between receiving the transmission and transmitting the feedback.

In method 500, at Block 506, a NACK feedback can be received, from the receiving node, for at least a portion of the message data or redundancy bits. In an aspect, feedback processing component 456, e.g., in conjunction with processor(s) 412, memory/memories 416, transceiver 402, waveform transmitting component 442, etc., can receive and/or process, from the receiving node, the NACK feedback for at least the portion of the message data or redundancy bits. For example, as described, where multiplexing is per-message, feedback processing component 456 can receive the NACK feedback for the message, or where multiplexing is per-symbol, feedback processing component 456 can receive the NACK feedback for one or more symbols (or corresponding blocks of the message). For example, feedback processing component 456 can receive the feedback from the receiving node in time and/or frequency resources defined for feedback, such as based on a K1_0 offset parameter in 5G NR, over a set of subcarriers or in a frequency band allocated for the transmission for which feedback is provided, etc. Where NACK feedback is received, for example, waveform transmitting component 442 can retransmit the message and/or corresponding block for which NACK feedback is provided, in accordance with various examples described herein.

In method 500, at Block 508, at least a portion of the message data or redundancy bits can be retransmitted to the receiving node and based on receiving the NACK feedback. In an aspect, peaky waveform component 454, e.g., in conjunction with processor(s) 412, memory/memories 416, transceiver 402, waveform transmitting component 442, etc., can retransmit, to the receiving node and based on receiving the NACK feedback, at least the portion of the message data or redundancy bits. For example, peaky waveform component 454 can transmit the message data or redundancy bits as another peaky transmission. In addition, for example, where multiplexing is per-message, peaky waveform component 454 can retransmit the message data and/or redundancy bits using the same peaky transmission (e.g., using the same different sets of subcarriers and duty cycle as the initial transmission), or can retransmit the message data and/or redundancy bits using a different peaky transmission than the initial transmission. In another example, where multiplexing is per-symbol, peaky waveform component 454 can retransmit a corresponding block and/or redundancy bits using the same peaky transmission (e.g., using the same set of subcarriers as the initial transmission of the block), or can retransmit the block and redundancy bits using a different peaky transmission than the initial transmission of the block. Where multiplexing is per-symbol, for example, peaky waveform component 454 can retransmit the symbol before an initial transmission of another symbol including a block of the same message.

In method 600, at Block 608, a retransmission of at least the portion of the message data or redundancy bits can be received from the transmitting node based on transmitting the NACK feedback. In an aspect, waveform processing component 342, e.g., in conjunction with processor(s) 312, memory/memories 316, transceiver 302, etc., can receive and/or process, from the transmitting node and based on transmitting the NACK feedback, the retransmission of at least the portion of the message data or redundancy bits. For example, as described, this can include waveform processing component 342 receiving or processing a retransmission of the message over multiple symbols, where multiplexing is per-message, or receiving or processing a retransmission of a given symbol including a corresponding block of message data, where the multiplexing is per-symbol.

In method 600, optionally at Block 610, at least the multiple symbols and a different set of multiple symbols can be soft-combined. In an aspect, demultiplexing component 354, e.g., in conjunction with processor(s) 312, memory/memories 316, transceiver 302, waveform processing component 342, etc., can soft-combine at least the multiple symbols and/or a different set of multiple symbols. For example, demultiplexing component 354 can receive the multiple symbols and/or different set of multiple symbols from the transmitting node and can perform soft-combining over the symbols that comprise the message. For example, demultiplexing component 354 can soft-combine symbols from the initial transmission with symbols from one or more retransmissions to receive, process, or decode the message and/or each of the corresponding symbols.

In method 500, optionally at Block 510, an adaptive time for receiving ACK/NACK feedback can be set based on a number of the multiple symbols. In an aspect, feedback processing component 456, e.g., in conjunction with processor(s) 412, memory/memories 416, transceiver 402, waveform transmitting component 442, etc., can set, based on the number of the multiple symbols, the adaptive timer for receiving the ACK/NACK feedback. For example, for a given number of symbols comprising the message, feedback processing component 456 can set the adaptive timer for receiving ACK/NACK feedback to allow the receiving node enough time to receive the message. Then, if feedback processing component 456 detects that NACK feedback for the message is not received within a time corresponding to the adaptive timer (e.g., before the adaptive timer expires after setting), feedback processing component 456 can assume the transmission is received and that retransmission is not needed, as described herein.

In method 500, optionally at Block 512, for per-symbol multiplexing, block data and redundancy bits associated with a second symbol can be retransmitted along with additional redundancy bits based on receiving the NACK feedback for one symbol and NACK feedback for a second symbol of the multiple symbols. In an aspect, peaky waveform component 454, e.g., in conjunction with processor(s) 412, memory/memories 416, transceiver 402, waveform transmitting component 442, etc., can retransmit, based on receiving the NACK feedback for one symbol and NACK feedback for a second symbol of the multiple symbols, block data and redundancy bits associated with the second symbol along with additional redundancy bits. For example, peaky waveform component 454 can include the additional redundancy bits for the second symbol based on detecting multiple NACKs in an attempt to improve reception quality for the second symbol (and/or subsequent symbols corresponding to blocks of the message).

In method 600, optionally at Block 612, a retransmission of block data and redundancy bits associated with the second symbol can be received with additional redundancy bits based on transmitting the NACK feedback for one symbol and NACK feedback for a second symbol of the multiple symbols. In an aspect, waveform processing component 342, e.g., in conjunction with processor(s) 312, memory/memories 316, transceiver 302, etc., can receive, based on transmitting the NACK feedback for one symbol and NACK feedback for a second symbol of the multiple symbols, a retransmission of block data and redundancy bits associated with the second symbol along with additional redundancy bits. As described, this can improve reliability for the retransmission of the second symbol. In addition, in an example, subsequent symbols may also include additional redundancy bits based on a number of NACK feedback transmissions for the blocks of the message.

In method 500, optionally at Block 514, a configuration indicating one or more of the number of symbols, an indication that retransmitting includes retransmitting all of the message data and redundancy bits, or an indication that retransmitting includes additional redundancy bits can be transmitted to the receiving node. In an aspect, configuring component 458, e.g., in conjunction with processor(s) 412, memory/memories 416, transceiver 402, waveform transmitting component 442, etc., can transmit, to the receiving node, the configuration indicating one or more of the number of symbols, the indication that retransmitting includes retransmitting all of the message data and redundancy bits, or the indication that retransmitting includes additional redundancy bits. For example, configuring component 458 can transmit the configuration to the receiving node in radio resource control (RRC) signaling, media access control-control element (MAC-CE), downlink control information (DCI), etc. to indicate one or more of the number of symbols or indicators described herein. This can allow the receiving node to know the number of symbols used to transmit message data, whether retransmissions include all of the message data and redundancy bits, whether retransmission include additional redundancy bits, etc., in accordance with various aspects described herein.

In method 600, optionally at Block 614, a configuration indicating one or more of the number of symbols, an indication that retransmitting includes retransmitting all of the message data and redundancy bits, or an indication that retransmitting includes additional redundancy bits can be received from the transmitting node. In an aspect, configuration processing component 356, e.g., in conjunction with processor(s) 312, memory/memories 316, transceiver 302, waveform processing component 342, etc., can receive and/or process, from the transmitting node, the configuration indicating one or more of the number of symbols, the indication that retransmitting includes retransmitting all of the message data and redundancy bits, or the indication that retransmitting includes additional redundancy bits. For example, configuration processing component 356 can receive the configuration in RRC signaling, MAC-CE, DCI, etc. to indicate one or more of the number of symbols or indicators described herein. In this regard, for example, waveform processing component 342 can receive the message (e.g., based on the number of symbols), receive retransmissions (e.g., as include all message data and redundancy bits and/or additional redundancy bits, etc.) based on the configuration.

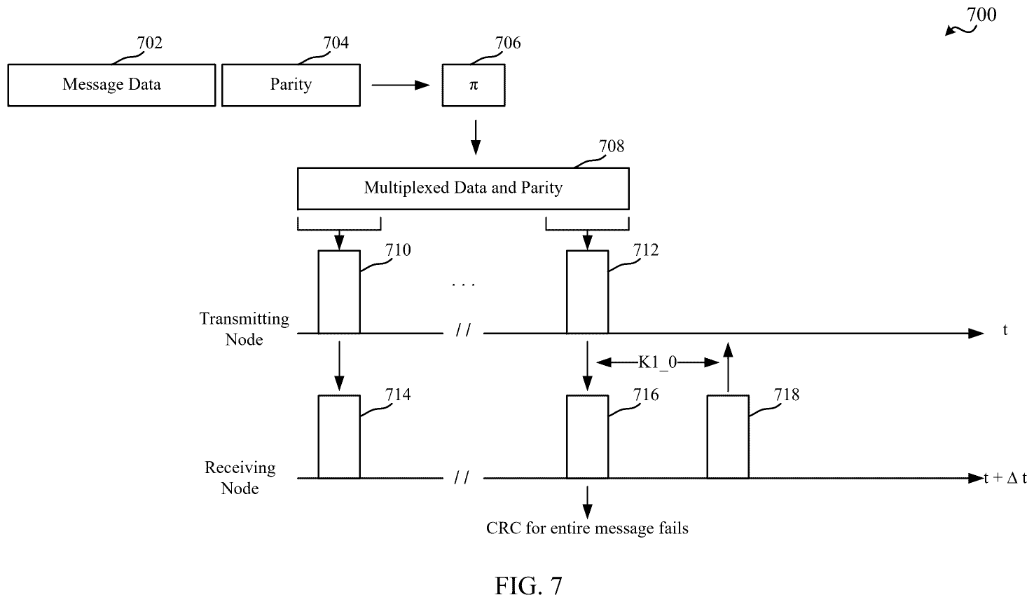

FIG. 7 illustrates an example of a communication timeline 700 between a transmitting node and receiving node based on per-message multiplexing of message data and parity bits, in accordance with aspects described herein. The communication timeline 700 can be for a time, t, for a transmitting node and/or a time, t+Δt, for the receiving node, where Δt is an offset between a time the transmitting node transmits a signal and the receiving node receives the signal. The transmitting node can input message data 702 of a message and parity bits 704 to an interleaver 706, which can generate multiplexed data and parity 708. The transmitting node can transmit various symbols using noncoherent peaky transmissions, including a first parity symbol 710 and a Mth parity symbol 712 that include each include portions of the multiplexed message data and parity bits 708. The receiving node can receive the first parity symbol 714 and the Mth parity symbol 716, which may be the last symbol of the message. The receiving node can perform CRC or FEC, which may fail. Where the CRC or FEC fails, the receiving node can transmit a feedback symbol 718 indicating NACK feedback for the message (e.g., after K1_0 offset) after the entire message is received. In this example, the transmitting node can retransmit the message, as described herein, which may include using the same peaky transmissions used to transmit the initial symbols 710 and 712 of the message (e.g., the same different sets of subcarriers and/or duty cycle) or different peaky transmissions.

In this example, the receiving node can check for success of the transmission after receiving all the peaky symbols of interest, and the retransmission can therefore be decided after receiving all the peaky symbols. The receiver node can send the feedback to the transmitting node as a peaky symbol as well, which may occur after a predetermined or configured number of slots and/or symbols, which may be described by K1_0 parameter. The feedback can include ACK/NACK information for the success of the message, as described herein. In some examples, the transmitting node can configure the receiving node with K1_0 prior to transmission (e.g., K1 in DCI defined in 5G NR). In an example, the receiving node can aggregate other indication bits (e.g., ACK/NACK of some other previous messages, remaining energy level, etc.), and send them along with the peaky symbol carrying current ACK/NACK feedback. In some examples, such a peaky symbol carrying ACK/NACK can still be transmitted with small probability of error if the duty cycle is appropriately determined. In an example, the transmitting node may set an adaptive timer based the number of peaky symbols, as described above, and may assume the transmission is successful if no NACK is received before timer expires (e.g., no explicit ACK may be expected). If a NACK is received, the transmitting node can retransmit the entire message by sending the same peaky symbols with no change, or using an adaptive mechanism (e.g., incremental redundancy mechanism), as described herein.

For example, retransmitting the same peaky symbols can allow for reducing the power consumption as the peaky symbols are not recomputed prior to retransmission, and the transmitting node can store only the indices of energy-bearing resource elements (REs) or subcarriers. This may use less buffer space and may be activated only if the retransmission is opted in for the current link. The success of this option may depend on whether the receiver is equipped with soft-combining capability, as described above, which can buffer peaky symbols from the previous round to be soft-combined with the retransmitted ones.

For example, retransmitting with incremental redundancy can include configuring retransmitted peaky symbols to be formed using various subset of data and redundancy bits, where the overall retransmission mechanism can be provided in layer 1 (L1). The retransmission may be configured to send (i) additional redundancy bits (e.g., only), or (ii) a mix of data and redundancy. Sending more parity bits may help recover the error from the previous transmission without soft-combining. Soft-combining can be provided for the mix of data and redundancy to achieve error performance improvement (although each transmission may be self-decodable). As described, the transmitting node can configure the receiver beforehand (e.g., via L1 indication which might be a part of retransmission) on whether retransmission is using the same peaky symbols or using incremental redundancy.

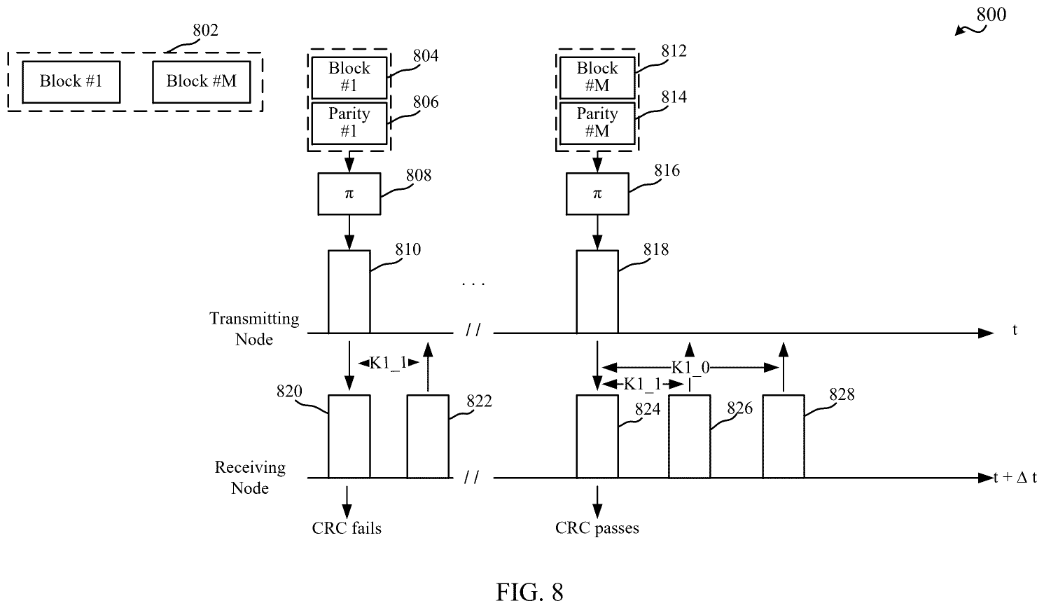

FIG. 8 illustrates an example of a communication timeline 800 between a transmitting node and receiving node based on per-symbol multiplexing of message data and parity bits, in accordance with aspects described herein. The transmitting node can split the message data into multiple blocks 802, including block #1 and block #M. Each block can be multiplexed with parity bits for transmission as a symbol, including block #1 804 being multiplexed with parity #1 806 using interleaver 808 for transmission in symbol 810, and block #M 812 being multiplexed with parity #M 814 using interleaver 816 for transmission in symbol 818. The receiving node can receive the symbol 820 including block #1 804, and can perform CRC or FEC per block. CRC can fail for symbol 820, and the receiving node can transmit a feedback symbol 822 indicating NACK after a time offset K1_1. The receiving node can receive the symbol 824 including block #M 812, and can perform CRC or FEC per block. CRC can pass for symbol 824, and the receiving node can transmit a feedback symbol 826 indicating ACK after a time offset K1_1, or can merge the ACK with the NACK for symbol 820 in feedback symbol 828 transmitted after a time offset K1_0.

In this example, redundancy can be separately computed or added for each peaky symbol (e.g., per-symbol redundancy), with the retransmission mechanism as follows. In per-symbol redundancy, the success of each peaky symbol can be determined as it is received (e.g., without necessarily waiting for a next symbol), and its ACK/NACK feedback can be sent either (i) before waiting for other peaky symbols (e.g., using K1_1 parameter), or (ii) merged with ACK/NACK responses of a few or all peaky symbols for the message and sent together (e.g., K1_0). In one example, the transmitting node can transmit feedback symbols as described for per-message multiplexing, and can select different K1_1 for each peaky symbol so that their ACK/NACK response aligns with K1_0. In an example, if a peaky symbol fails to pass CRC or FEC, then additional parity bits may be included in the retransmission of that particular symbol or for one or more future symbols (e.g., of the same message or a different message), as described herein. Thus, it may be possible, by adaptive retransmission, to proactively adjust the redundancy of the future peaky symbols based on the receive success of the current peaky symbol. In another example, an identifier (e.g., an index of the peaky symbol within the message) can also be added to ACK/NACK response to describe for which peaky symbol a transmitted ACK/NACK feedback indicates ACK or NACK.

FIG. 9 is a block diagram of a MIMO communication system 900 including a base station 102 and a UE 104. The MIMO communication system 900 may illustrate aspects of the wireless communication access network 100 described with reference to FIG. 1. The base station 102 may be an example of aspects of the base station 102 described with reference to FIG. 1. The base station 102 may be equipped with antennas 934 and 935, and the UE 104 may be equipped with antennas 952 and 953. In the MIMO communication system 900, the base station 102 may be able to send data over multiple communication links at the same time. Each communication link may be called a “layer” and the “rank” of the communication link may indicate the number of layers used for communication. For example, in a 2×2 MIMO communication system where base station 102 transmits two “layers,” the rank of the communication link between the base station 102 and the UE 104 is two.

At the base station 102, a transmit (Tx) processor 920 may receive data from a data source. The transmit processor 920 may process the data. The transmit processor 920 may also generate control symbols or reference symbols. A transmit MIMO processor 930 may perform spatial processing (e.g., precoding) on data symbols, control symbols, or reference symbols, if applicable, and may provide output symbol streams to the transmit modulator/demodulators 932 and 933. Each modulator/demodulator 932 through 933 may process a respective output symbol stream (e.g., for OFDM, etc.) to obtain an output sample stream. Each modulator/demodulator 932 through 933 may further process (e.g., convert to analog, amplify, filter, and upconvert) the output sample stream to obtain a DL signal. In one example, DL signals from modulator/demodulators 932 and 933 may be transmitted via the antennas 934 and 935, respectively.

The UE 104 may be an example of aspects of the UEs 104 described with reference to FIGS. 1 and 3. At the UE 104, the UE antennas 952 and 953 may receive the DL signals from the base station 102 and may provide the received signals to the modulator/demodulators 954 and 955, respectively. Each modulator/demodulator 954 through 955 may condition (e.g., filter, amplify, downconvert, and digitize) a respective received signal to obtain input samples. Each modulator/demodulator 954 through 955 may further process the input samples (e.g., for OFDM, etc.) to obtain received symbols. A MIMO detector 956 may obtain received symbols from the modulator/demodulators 954 and 955, perform MIMO detection on the received symbols, if applicable, and provide detected symbols. A receive (Rx) processor 958 may process (e.g., demodulate, deinterleave, and decode) the detected symbols, providing decoded data for the UE 104 to a data output, and provide decoded control information to a processor(s) 980, or memory/memories 982.

The processor(s) 980 may in some cases execute stored instructions to instantiate a waveform processing component 342 (see e.g., FIGS. 1 and 3).

On the uplink (UL), at the UE 104, a transmit processor 964 may receive and process data from a data source. The transmit processor 964 may also generate reference symbols for a reference signal. The symbols from the transmit processor 964 may be precoded by a transmit MIMO processor 966 if applicable, further processed by the modulator/demodulators 954 and 955 (e.g., for single carrier-FDMA, etc.), and be transmitted to the base station 102 in accordance with the communication parameters received from the base station 102. At the base station 102, the UL signals from the UE 104 may be received by the antennas 934 and 935, processed by the modulator/demodulators 932 and 933, detected by a MIMO detector 936 if applicable, and further processed by a receive processor 938. The receive processor 938 may provide decoded data to a data output and to the processor(s) 940 or memory/memories 942.

The processor(s) 940 may in some cases execute stored instructions to instantiate a waveform transmitting component 442 (see e.g., FIGS. 1 and 4).

The components of the UE 104 may, individually or collectively, be implemented with one or more ASICs adapted to perform some or all of the applicable functions in hardware. Each of the noted modules may be a means for performing one or more functions related to operation of the MIMO communication system 900. Similarly, the components of the base station 102 may, individually or collectively, be implemented with one or more application specific integrated circuits (ASICs) adapted to perform some or all of the applicable functions in hardware. Each of the noted components may be a means for performing one or more functions related to operation of the MIMO communication system 900.

The following aspects are illustrative only and aspects thereof may be combined with aspects of other embodiments or teaching described herein, without limitation.

Aspect 1 is a method for wireless communication at a transmitting node including multiplexing message data, to be transmitted to a receiving node, with redundancy bits on a per-message or per-symbol basis, transmitting, to the receiving node, the multiplexed message data and redundancy bits in a different subset of assigned subcarriers in each of multiple symbols of a noncoherent transmission according to a duty cycle, receiving, from the receiving node, a NACK feedback for at least a portion of the message data or redundancy bits, and retransmitting, to the receiving node and based on receiving the NACK feedback, at least the portion of the message data or redundancy bits.

In Aspect 2, the method of Aspect 1 includes where the multiplexing includes multiplexing the message data with the redundancy bits as CRC bits or parity bits for FEC across the multiple symbols.

In Aspect 3, the method of Aspect 2 includes where the receiving the NACK feedback occurs after transmitting all of the multiple symbols to the receiving node.

In Aspect 4, the method of any of Aspects 2 or 3 includes where the receiving the NACK feedback includes receiving the NACK feedback in a second subset of the assigned subcarriers and in a configured number of symbols following a last symbol of the multiple symbols.

In Aspect 5, the method of Aspect 4 includes transmitting, to the receiving node, a configuration indicating the number of symbols.

In Aspect 6, the method of any of Aspects 2 to 5 includes where the NACK feedback includes feedback for other message data transmitted to the receiving node.

In Aspect 7, the method of any of Aspects 2 to 6 includes setting, based on a number of the multiple symbols, an adaptive timer, where the NACK feedback is received during the adaptive timer.

In Aspect 8, the method of any of Aspects 2 to 7 includes where the retransmitting at least the portion of the message data or redundancy bits includes retransmitting at least all of the redundancy bits to the receiving node.

In Aspect 9, the method of Aspect 8 includes where the retransmitting further includes retransmitting all of the message data to the receiving node, and where retransmitting all of the message data and the redundancy bits includes retransmitting all of the message data and the redundancy bits in the same subcarriers, as the different subset of assigned subcarriers in each of the multiple symbols, over a different set of multiple symbols.

In Aspect 10, the method of Aspect 9 includes transmitting, to the receiving node, a configuration indicating that the retransmitting includes retransmitting all of the message data and the redundancy bits.

In Aspect 11, the method of any of Aspects 8 to 10 includes where the retransmitting further includes transmitting additional redundancy bits to the receiving node.

In Aspect 12, the method of Aspect 11 includes transmitting, to the receiving node, a configuration indicating that the retransmitting includes retransmitting additional redundancy bits.

In Aspect 13, the method of any of Aspects 1 to 12 includes where the multiplexing includes multiplexing block data of the message data in each symbol with the redundancy bits as CRC bits or parity bits for FEC for the block data.

In Aspect 14, the method of Aspect 13 includes where the receiving the NACK feedback occurs before transmitting a last symbol of the multiple symbols to the receiving node.

In Aspect 15, the method of any of Aspects 13 or 14 includes where receiving the NACK feedback includes receiving the NACK feedback for a portion of the multiple symbols before transmitting a last symbol of the multiple symbols to the receiving node.

In Aspect 16, the method of any of Aspects 13 to 15 includes where the receiving the NACK feedback includes receiving the NACK feedback in a second subset of the assigned subcarriers and in a configured number of symbols following a symbol to which the NACK feedback corresponds.

In Aspect 17, the method of Aspect 16 includes transmitting, to the receiving node, a configuration indicating the number of symbols.

In Aspect 18, the method of any of Aspects 16 or 17 includes where the number of symbols is different than a second number of symbols after which feedback is configured to be received for a second symbol in the multiple symbols.

In Aspect 19, the method of any of Aspects 13 to 18 includes setting an adaptive timer, where the NACK feedback is received during the adaptive timer.

In Aspect 20, the method of any of Aspects 13 to 19 includes where the retransmitting at least the portion of the message data and the redundancy bits includes retransmitting the block data and redundancy bits of one symbol of the multiple symbols.

In Aspect 21, the method of Aspect 20 includes where the retransmitting further includes retransmitting additional redundancy bits with the block data of the one symbol.

In Aspect 22, the method of any of Aspects 20 or 21 includes retransmitting, based on receiving the NACK feedback for the one symbol and NACK feedback for a second symbol of the multiple symbols, block data and redundancy bits associated with the second symbol along with additional redundancy bits.

In Aspect 23, the method of any of Aspects 20 to 22 includes where the NACK feedback includes an identifier of the one symbol of the multiple symbols.

Aspect 24 is a method for wireless communication at a receiving node that includes receiving, from a transmitting node, message data and redundancy bits multiplexed in a different subset of assigned subcarriers in each of multiple symbols of a noncoherent transmission according to a duty cycle, performing a CRC or FEC for at least a portion of the message data or redundancy bits, transmitting, to the transmitting node, a NACK feedback for at least the portion of the message data or redundancy bits, and receiving, from the transmitting node and based on transmitting the NACK feedback, a retransmission of at least the portion of the message data or redundancy bits.

In Aspect 25, the method of Aspect 24 includes where the message data and the redundancy bits are multiplexed as CRC bits or parity bits for FEC across the multiple symbols.

In Aspect 26, the method of Aspect 25 includes where the performing the CRC or FEC includes performing the CRC or FEC over the message data and redundancy bits received in all of the multiple symbols, and where the transmitting the NACK feedback occurs after performing the CRC or FEC.

In Aspect 27, the method of any of Aspects 25 or 26 includes where the transmitting the NACK feedback includes transmitting the NACK feedback in a second subset of the assigned subcarriers and in a configured number of symbols following a last symbol of the multiple symbols.

In Aspect 28, the method of Aspect 27 includes receiving, from the transmitting node, a configuration indicating the number of symbols.

In Aspect 29, the method of any of Aspects 25 to 28 includes where the NACK feedback includes feedback for other message data transmitted to the receiving node.

In Aspect 30, the method of any of Aspects 25 to 29 includes where the retransmission of at least the portion of the message data or redundancy bits includes at least all of the redundancy bits.

In Aspect 31, the method of Aspect 30 includes where the retransmission further includes all of the message data, and where receiving the retransmission of all of the message data and the redundancy bits includes receiving the retransmission all of the message data and the redundancy bits in the same subcarriers, as the different subset of assigned subcarriers in each of the multiple symbols, over a different set of multiple symbols.

In Aspect 32, the method of Aspect 31 includes soft-combining at least the multiple symbols and the different set of multiple symbols, and performing the CRC or FEC over the soft-combined symbols.

In Aspect 33, the method of any of Aspects 31 or 32 includes receiving, from the transmitting node, a configuration indicating that the retransmission includes all of the message data and the redundancy bits.

In Aspect 34, the method of any of Aspects 30 to 33 includes where the retransmission includes additional redundancy bits.

In Aspect 35, the method of Aspect 34 includes receiving, from the transmitting node, a configuration indicating that the retransmission includes additional redundancy bits.

In Aspect 36, the method of any of Aspects 24 to 35 includes where the message data and redundancy bits are multiplexed as block data of the message data multiplexed with the redundancy bits in each symbol of the multiple symbols with the redundancy bits as CRC bits or parity bits for FEC for the block data.

In Aspect 37, the method of Aspect 36 includes where the transmitting the NACK feedback occurs before receiving a last symbol of the multiple symbols.

In Aspect 38, the method of any of Aspects 36 or 37 includes where transmitting the NACK feedback includes transmitting the NACK feedback for a portion of the multiple symbols before receiving a last symbol of the multiple symbols.

In Aspect 39, the method of any of Aspects 36 to 38 includes where the transmitting the NACK feedback includes transmitting the NACK feedback in a second subset of the assigned subcarriers and in a configured number of symbols following a symbol to which the NACK feedback corresponds.

In Aspect 40, the method of Aspect 39 includes receiving, from the transmitting node, a configuration indicating the number of symbols.

In Aspect 41, the method of any of Aspects 39 or 40 includes where the number of symbols is different than a second number of symbols after which feedback is configured to be transmitted for a second symbol in the multiple symbols.

In Aspect 42, the method of any of Aspects 36 to 41 includes where the retransmission includes the block data and redundancy bits of one symbol of the multiple symbols.

In Aspect 43, the method of Aspect 42 includes where the retransmission further includes additional redundancy bits with the block data of the one symbol.

In Aspect 44, the method of any of Aspects 42 or 43 includes receiving, based on transmitting the NACK feedback for the one symbol and NACK feedback for a second symbol of the multiple symbols, a retransmission of block data and redundancy bits associated with the second symbol along with additional redundancy bits.

In Aspect 45, the method of any of Aspects 42 to 44 includes where the NACK feedback includes an identifier of the one symbol of the multiple symbols.

Aspect 46 is an apparatus for wireless communication including one or more processors, one or more memories coupled with the one or more processors, and instructions stored in the one or more memories and operable, when executed by the one or more processors, to cause the apparatus to perform any of the methods of Aspects 1 to 45.

Aspect 47 is an apparatus for wireless communication including means for performing any of the methods of Aspects 1 to 45.

Aspect 48 is one or more computer-readable media including code executable by one or more processors for wireless communications, the code including code for performing any of the methods of Aspects 1 to 45.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

The various illustrative blocks and components described in connection with the disclosure herein may be implemented or performed with a specially programmed device, such as but not limited to a processor, a digital signal processor (DSP), an ASIC, a field programmable gate array (FPGA) or other programmable logic device, a discrete gate or transistor logic, a discrete hardware component, or any combination thereof designed to perform the functions described herein. A specially programmed processor may be a microprocessor, but in the alternative, the processor may be any conventional processor, controller, microcontroller, or state machine. A specially programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above can be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that can be accessed by a general purpose or special purpose computer. By way of example, and not limitation, computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise. Thus, the disclosure is not to be limited to the examples and designs described herein but is to be accorded the widest scope consistent with the principles and novel features disclosed herein.

What is claimed is:

1. An apparatus for wireless communication, comprising:
a transceiver;
one or more memories configured to, individually or in combination, store instructions; and
one or more processors communicatively coupled with the one or more memories, wherein the one or more processors are, individually or in combination, configured to execute the instructions to cause the apparatus to:
multiplex message data, to be transmitted to a receiving node, with redundancy bits on a per-message or per-symbol basis;
transmit, to the receiving node, the multiplexed message data and redundancy bits in a different subset of assigned subcarriers in each of multiple symbols of a noncoherent transmission according to a duty cycle;
receive, from the receiving node, a negative-acknowledgement (NACK) feedback for at least a portion of the message data or redundancy bits; and
retransmit, to the receiving node and based on receiving the NACK feedback, at least the portion of the message data or redundancy bits.

2. The apparatus of claim 1, wherein the multiplexing includes multiplexing the message data with the redundancy bits as cyclic redundancy check (CRC) bits or parity bits for forward error correction (FEC) across the multiple symbols.

3. The apparatus of claim 2, wherein the one or more processors are, individually or in combination, configured to execute the instructions to cause the apparatus to receive the NACK feedback after transmitting all of the multiple symbols to the receiving node.

4. The apparatus of claim 2, wherein the one or more processors are, individually or in combination, configured to execute the instructions to cause the apparatus to receive the NACK feedback in a second subset of the assigned subcarriers and in a configured number of symbols following a last symbol of the multiple symbols.

5. The apparatus of claim 4, wherein the one or more processors are, individually or in combination, configured to execute the instructions to cause the apparatus to transmit, to the receiving node, a configuration indicating the number of symbols.

6. The apparatus of claim 2, wherein the NACK feedback includes feedback for other message data transmitted to the receiving node.

7. The apparatus of claim 2, wherein the one or more processors are, individually or in combination, configured to execute the instructions to cause the apparatus to set, based on a number of the multiple symbols, an adaptive timer, wherein the NACK feedback is received during the adaptive timer.

8. The apparatus of claim 2, wherein the one or more processors are, individually or in combination, configured to execute the instructions to cause the apparatus to retransmit at least all of the redundancy bits to the receiving node.

9. The apparatus of claim 8, wherein the one or more processors are, individually or in combination, configured to execute the instructions to cause the apparatus to retransmit all of the message data to the receiving node, and retransmit all of the message data and the redundancy bits in the same subcarriers, as the different subset of assigned subcarriers in each of the multiple symbols, over a different set of multiple symbols.

10. The apparatus of claim 9, wherein the one or more processors are, individually or in combination, configured to execute the instructions to cause the apparatus to transmit, to the receiving node, a configuration indicating that the retransmitting includes retransmitting all of the message data and the redundancy bits.

11. The apparatus of claim 8, wherein the one or more processors are, individually or in combination, configured to execute the instructions to cause the apparatus to transmit additional redundancy bits to the receiving node.

12. The apparatus of claim 11, wherein the one or more processors are, individually or in combination, configured to execute the instructions to cause the apparatus to transmit, to the receiving node, a configuration indicating that the retransmitting includes retransmitting additional redundancy bits.

13. The apparatus of claim 1, wherein the one or more processors are, individually or in combination, configured to execute the instructions to cause the apparatus to multiplex block data of the message data in each symbol with the redundancy bits as cyclic redundancy check (CRC) bits or parity bits for forward error correction (FEC) for the block data.

14. The apparatus of claim 13, wherein the one or more processors are, individually or in combination, configured to execute the instructions to cause the apparatus to receive the NACK feedback before transmitting a last symbol of the multiple symbols to the receiving node.

15. The apparatus of claim 13, wherein the one or more processors are, individually or in combination, configured to execute the instructions to cause the apparatus to receive the NACK feedback for a portion of the multiple symbols before transmitting a last symbol of the multiple symbols to the receiving node.

16. The apparatus of claim 13, wherein the one or more processors are, individually or in combination, configured to execute the instructions to cause the apparatus to receive the NACK feedback in a second subset of the assigned subcarriers and in a configured number of symbols following a symbol to which the NACK feedback corresponds.

17. The apparatus of claim 16, wherein the one or more processors are, individually or in combination, configured to execute the instructions to cause the apparatus to transmit, to the receiving node, a configuration indicating the number of symbols.

18. The apparatus of claim 16, wherein the number of symbols is different than a second number of symbols after which feedback is configured to be received for a second symbol in the multiple symbols.

19. The apparatus of claim 13, wherein the one or more processors are, individually or in combination, configured to execute the instructions to cause the apparatus to set an adaptive timer, wherein the NACK feedback is received during the adaptive timer.

20. The apparatus of claim 13, wherein the one or more processors are, individually or in combination, configured to execute the instructions to cause the apparatus to retransmit at least the portion of the message data and the redundancy bits as the block data and redundancy bits of one symbol of the multiple symbols.

21. The apparatus of claim 20, wherein the one or more processors are, individually or in combination, configured to execute the instructions to cause the apparatus to retransmit additional redundancy bits with the block data of the one symbol.

22. The apparatus of claim 20, wherein the one or more processors are, individually or in combination, configured to execute the instructions to cause the apparatus to retransmit, based on receiving the NACK feedback for the one symbol and NACK feedback for a second symbol of the multiple symbols, block data and redundancy bits associated with the second symbol along with additional redundancy bits.

23. The apparatus of claim 20, wherein the NACK feedback includes an identifier of the one symbol of the multiple symbols.

24. An apparatus for wireless communication, comprising:
a transceiver;
one or more memories configured to, individually or in combination, store instructions; and
one or more processors communicatively coupled with the one or more memories, wherein the one or more processors are, individually or in combination, configured to execute the instructions to cause the apparatus to:
receive, from a transmitting node, message data and redundancy bits multiplexed in a different subset of assigned subcarriers in each of multiple symbols of a noncoherent transmission according to a duty cycle;
perform a cyclic redundancy check (CRC) or forward error correction (FEC) for at least a portion of the message data or redundancy bits;
transmit, to the transmitting node, a negative-acknowledgement (NACK) feedback for at least the portion of the message data or redundancy bits; and
receive, from the transmitting node and based on transmitting the NACK feedback, a retransmission of at least the portion of the message data or redundancy bits.

25. The apparatus of claim 24, wherein the message data and the redundancy bits are multiplexed as CRC bits or parity bits for FEC across the multiple symbols.

26. The apparatus of claim 25, wherein the one or more processors are, individually or in combination, configured to execute the instructions to cause the apparatus to perform the CRC or FEC over the message data and redundancy bits received in all of the multiple symbols, and wherein the one or more processors are, individually or in combination, configured to execute the instructions to cause the apparatus to transmit the NACK feedback after performing the CRC or FEC.

27. A method for wireless communication at a transmitting node, comprising:
multiplexing message data, to be transmitted to a receiving node, with redundancy bits on a per-message or per-symbol basis;
transmitting, to the receiving node, the multiplexed message data and redundancy bits in a different subset of assigned subcarriers in each of multiple symbols of a noncoherent transmission according to a duty cycle;
receiving, from the receiving node, a negative-acknowledgement (NACK) feedback for at least a portion of the message data or redundancy bits; and
retransmitting, to the receiving node and based on receiving the NACK feedback, at least the portion of the message data or redundancy bits.

28. The method of claim 27, wherein the multiplexing includes multiplexing the message data with the redundancy bits as cyclic redundancy check (CRC) bits or parity bits for forward error correction (FEC) across the multiple symbols.

29. A method for wireless communication at a receiving node, comprising:
receiving, from a transmitting node, message data and redundancy bits multiplexed in a different subset of assigned subcarriers in each of multiple symbols of a noncoherent transmission according to a duty cycle;
performing a cyclic redundancy check (CRC) or forward error correction (FEC) for at least a portion of the message data or redundancy bits;
transmitting, to the transmitting node, a negative-acknowledgement (NACK) feedback for at least the portion of the message data or redundancy bits; and
receiving, from the transmitting node and based on transmitting the NACK feedback, a retransmission of at least the portion of the message data or redundancy bits.

30. The method of claim 29, wherein the message data and the redundancy bits are multiplexed as CRC bits or parity bits for FEC across the multiple symbols.
